(19) United States
(12) Patent Application Publication
(10) Pub. No.: US 2023/0254996 A1
(43) Pub. Date: Aug. 10, 2023

(54) IMMERSION TANK ASSEMBLY

(71) Applicant: Scot Arthur Johnson, Woodview (CA)

(72) Inventor: Scot Arthur Johnson, Woodview (CA)

(21) Appl. No.: 18/105,978

(22) Filed: Feb. 6, 2023

Related U.S. Application Data
(60) Provisional application No. 63/307,295, filed on Feb. 7, 2022.

(51) Int. Cl. H05K 7/20

(52) U.S. Cl. CPC H05K 7/20272; H05K 7/20236; H05K 7/20772

(57) ABSTRACT

Various embodiments herein provide for an immersion tank assembly. In at least one embodiment, the immersion tank assembly comprises: a tank housing enclosure, the enclosure comprising: at least one interior compartment configured to retain one or more processing units immersed in dielectric cooling liquid; one or more side chambers surrounding the interior compartment, wherein the one or more side chambers are fluidically isolated from the interior compartment by one or more separation walls; and one or more fluid conduits in fluid communication with the each of the one or more side chambers, wherein the one or more fluid conduits are adapted to convey lower temperature water into the respective side chamber for cooling the dielectric cooling liquid in the at least one interior compartment, and to evacuate higher temperature water away from the respective side chamber.

### REFERENCE TO RELATED APPLICATIONS

This application claims the benefit of U.S. Provisional Application No. 63/307,295 filed on Feb. 7, 2022, the entire contents of which is incorporate herein by reference.

### FIELD

The described embodiments relate to tank assemblies, and in particular, to a an immersion tank assembly which may house one or more processing units.

### INTRODUCTION

Many datacenter facilities have very high power requirements and can require substantial cooling to maintain computing equipment within its acceptable operating conditions. It can be advantageous to locate such datacenter facilities in geographical locations with relatively low-cost electrical power, cold ambient air temperatures, or a combination of both. In a datacenter, electrical power is used for two things: to power the many microprocessors within, and to drive cooling of the microprocessors to maintain a safe operating temperature.

### SUMMARY OF THE VARIOUS EMBODIMENTS

The following introduction is provided to introduce the reader to the more detailed discussion to follow. The introduction is not intended to limit or define any claimed or as yet unclaimed invention. One or more inventions may reside in any combination or sub-combination of the elements or process steps disclosed in any part of this document including its claims and figures.

In accordance with at least one broad embodiment, there is provided an immersion tank assembly, comprising: a tank housing enclosure, the enclosure comprising: at least one interior compartment configured to retain one or more processing units immersed in dielectric cooling liquid; one or more side chambers surrounding the interior compartment, wherein the one or more side chambers are fluidically isolated from the interior compartment by one or more separation walls; and one or more fluid conduits in fluid communication with the each of the one or more side chambers, wherein the one or more fluid conduits are adapted to convey lower temperature water into the respective side chamber for cooling the dielectric cooling liquid in the at least one interior compartment, and to evacuate higher temperature water away from the respective side chamber.

In some embodiments, the separation walls are corrugated to maximize heat transfer between interior compartment and the side chambers.

In some embodiments, the tank housing enclosure comprise a bottom side and a top side, the top side being axially opposed from the bottom side along a vertical axis, and each of the one or more side chambers extends between the top and bottom sides.

In some embodiments, each fluid conduit, of the one or more fluid conduits, extends between a first end and a second end, the first end being fluidically coupled to a respective side chamber and the second end being fluidically coupled to a water cooling system.

In some embodiments, the one or more fluid conduits, coupled to each side chamber, comprise a first fluid conduit and a second fluid conduit, the first fluid conduit being used to transport cooled water from the water cooling system into the respective side chamber and the second fluid conduit being used to transport heated water away from the respective side chamber and back to the water cooling system.

In some embodiments, the first fluid conduit is an upper fluid conduit coupled to an upper portion of each side chamber, and the second fluid conduit is a lower fluid conduit coupled to a lower portion of each side chamber.

In some embodiments, the immersion tank assembly further comprises one or more agitators positioned inside the at least one interior compartment.

In some embodiments, the immersion tank assembly comprises an interior housing structure nested within an exterior housing structure, and the interior housing structure defines the interior compartment.

In some embodiments, the interior housing structure has a smaller volume size than the exterior housing structure such as to define the side chambers.

In some embodiments, the interior housing structure is manufactured from a heat conductive metal.

Other features and advantages of the present application will become apparent from the following detailed description. It should be understood, however, that the detailed description and the specific examples, while indicating embodiments of the application, are given by way of illustration only and the scope of the claims should not be limited by these embodiments, but should be given the broadest interpretation consistent with the description as a whole.

### BRIEF DESCRIPTION OF THE DRAWINGS

For a better understanding of the embodiments described herein and to show more clearly how they may be carried into effect, reference will now be made, by way of example only, to the accompanying drawings which show at least one exemplary embodiment, and in which:

FIG. 1A is a perspective view of an immersion tank assembly, in accordance with at least some embodiments;

FIG. 1B is a perspective view of an immersion tank assembly with a power supply unit, in accordance with some embodiments;

FIG. 2A is a perspective view of the immersion tank assembly of FIG. 1A, with a top openable lid removed;

FIG. 2B is a perspective, partially-exploded view of the immersion tank assembly of FIG. 1A;

FIG. 3 is a simplified block diagram of a water cooling system fluidically coupled to the immersion tank assembly;

FIG. 4A is a perspective view of an example embodiment of a housing enclosure of the immersion tank assembly;

FIG. 4B is a perspective view of the housing enclosure of FIG. 4A, with a top openable lid removed;

FIG. 4C is a perspective cross-sectional view of the housing enclosure of FIG. 4A, taken along the section line 4C-4C′ in FIG. 4A;

FIG. 4D is a top-down view of the cross-sectional view in FIG. 4C;

FIG. 4E is a perspective cross-sectional view of the housing enclosure of FIG. 4A, taken along the section line 4D-4D′ in FIG. 4A;

FIG. 4F is a perspective cross-sectional view of the housing enclosure of FIG. 4E, and showing one or more processing units mounted inside the housing enclosure;

FIG. 5A is a cross-sectional view of the housing enclosure of FIG. 4A, taken along the section line 4D-4D′ in FIG. 4A, and showing fluid flow there through;

FIG. 5B is a cross-sectional view of the housing enclosure of FIG. 4A, taken along the section line 4D-4D′ in FIG. 4A, and showing fluid flow, according to some other embodiments;

FIG. 5C is a cross-sectional view of the housing enclosure of FIG. 4A, taken along the section line 4D-4D′ in FIG. 4A, and showing fluid flow, according to still some other embodiments;

FIG. 5D is a cross-sectional view of the housing enclosure of FIG. 4A, taken along the section line 4D-4D′ in FIG. 4A, and showing fluid flow, according to still yet some other embodiments;

FIG. 5E is a cross-sectional view of the housing enclosure of FIG. 4A, taken along the section line 4D-4D′ in FIG. 4A, and showing fluid flow, according to some other embodiments;

FIG. 6A is a perspective, partially-exploded view of a housing enclosure, according to some embodiments;

FIG. 6B is a perspective exploded view of a housing enclosure, according to some embodiments; and

FIG. 6C is a perspective of an inner housing structure, according to some embodiments.

Further aspects and features of the example embodiments described herein will appear from the following description taken together with the accompanying drawings.

### DESCRIPTION OF VARIOUS EMBODIMENTS

Numerous embodiments are described in this application, and are presented for illustrative purposes only. The described embodiments are not intended to be limiting in any sense. The invention is widely applicable to numerous embodiments, as is readily apparent from the disclosure herein. Those skilled in the art will recognize that the present invention may be practiced with modification and alteration without departing from the teachings disclosed herein. Although particular features of the present invention may be described with reference to one or more particular embodiments or figures, it should be understood that such features are not limited to usage in the one or more particular embodiments or figures with reference to which they are described.

The terms “an embodiment,” “embodiment,” “embodiments,” “the embodiment,” “the embodiments,” “one or more embodiments,” “some embodiments,” and “one embodiment” mean “one or more (but not all) embodiments of the present invention(s),” unless expressly specified otherwise.

The terms “including,” “comprising” and variations thereof mean “including but not limited to,” unless expressly specified otherwise. A listing of items does not imply that any or all of the items are mutually exclusive, unless expressly specified otherwise. The terms “a,” “an” and “the” mean “one or more,” unless expressly specified otherwise.

As used herein and in the claims, two or more parts are said to be “coupled”, “connected”, “attached”, “joined”, “affixed”, or “fastened” where the parts are joined or operate together either directly or indirectly (i.e., through one or more intermediate parts), so long as a link occurs. As used herein and in the claims, two or more parts are said to be “directly coupled”, “directly connected”, “directly attached”, “directly joined”, “directly affixed”, or “directly fastened” where the parts are connected in physical contact with each other. As 25 used herein, two or more parts are said to be “rigidly coupled”, “rigidly connected”, “rigidly attached”, “rigidly joined”, “rigidly affixed”, or “rigidly fastened” where the parts are coupled so as to move as one while maintaining a constant orientation relative to each other. None of the terms “coupled”, “connected”, “attached”, “joined”, “affixed”, and “fastened” distinguish the manner in which two or more parts are joined together.

Further, although method steps may be described (in the disclosure and/or in the claims) in a sequential order, such methods may be configured to work in alternate orders. In other words, any sequence or order of steps that may be described does not necessarily indicate a requirement that the steps be performed in that order. The steps of methods described herein may be performed in any order that is practical. Further, some steps may be performed simultaneously.

As used herein and in the claims, a group of elements are said to ‘collectively’ perform an act where that act is performed by any one of the elements in the group, or performed cooperatively by two or more (or all) elements in the group.

As used herein and in the claims, a first element is said to be “received” in a second element where at least a portion of the first element is received in the second element unless specifically stated otherwise.

Some elements herein may be identified by a part number, which is composed of a base number followed by an alphabetical or subscript-numerical suffix (e.g. 112a, or 112₁). Multiple elements herein may be identified by part numbers that share a base number in common and that differ by their suffixes (e.g. 112₁, 112₂, and 112₃). All elements with a common base number may be referred to collectively or generically using the base number without a suffix (e.g. 112).

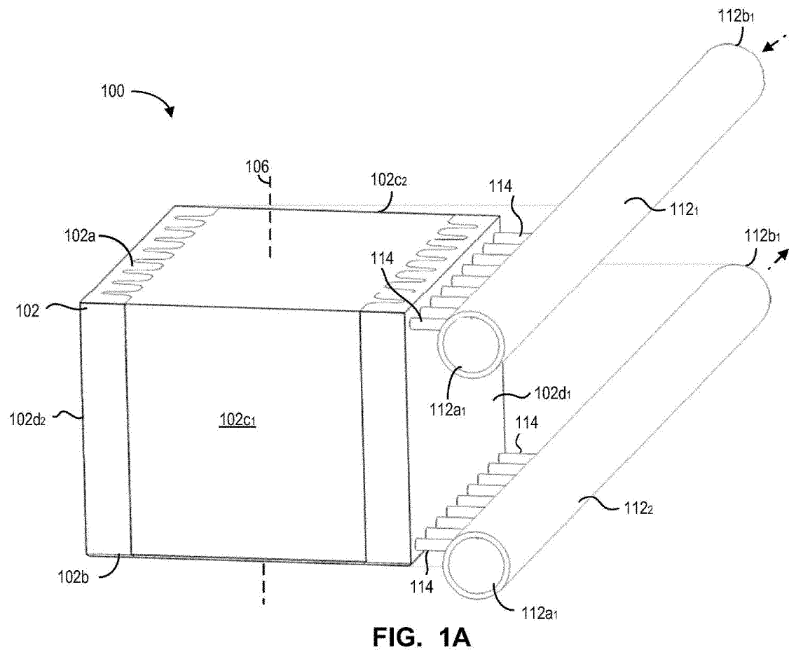

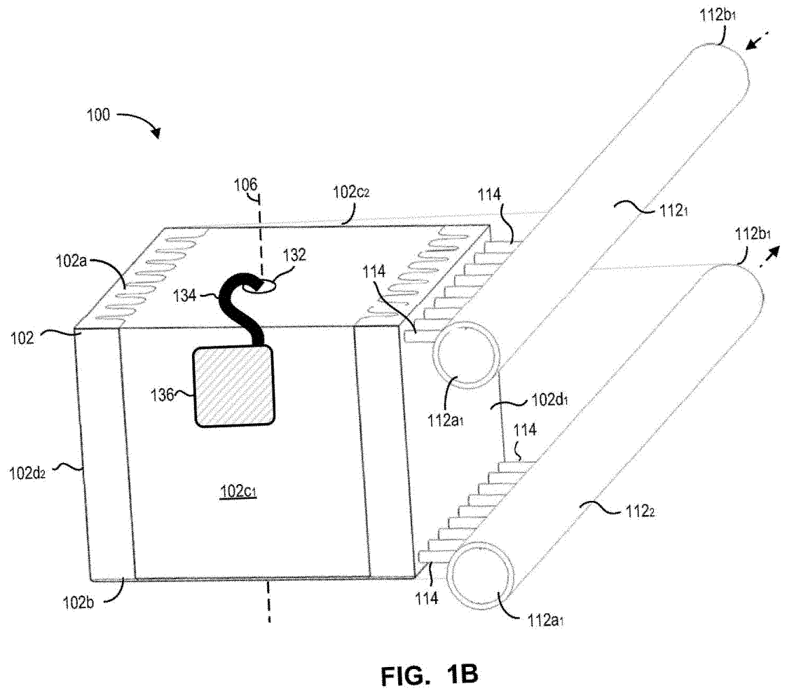

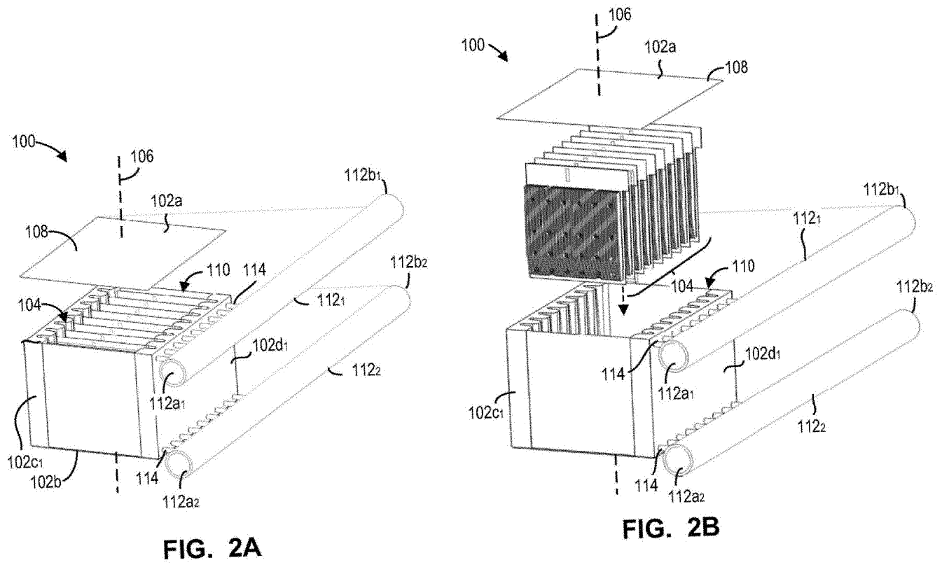

Reference is now made to FIGS. 1-2, which exemplify an example embodiment of an immersion tank assembly 100, in accordance with the teachings provided herein.

As shown, the immersion tank assembly 100 generally includes a tank housing enclosure 102. As best exemplified in FIGS. 2A and 2B, housing 102 can define an enclosure having an at least partially hollow interior 110. The hollow interior 110 can be used for retaining one or more processing units 104. In at least one embodiment, the processing units 104 may provide for a parallel processing function, such as may be required for performing mining cryptocurrencies, identifying large prime numbers, operating blockchain based information systems and many other such tasks. In some cases, processing units 104 may comprise miners for mining cryptocurrency.

In at least some embodiments, housing enclosure 102 may be constructed from rigid, weather resistant material capable of withstanding an outdoor environment. In this manner, housing 102 can provide for a generally weather resistant and enclosed volume in which other elements (i.e., processing units 104) can be installed.

As exemplified in FIG. 1A, in the upright position, housing enclosure 102 may include a top side or surface 102a, and an opposed bottom side surface 102b. Top and bottom surfaces 102a, 102b may be axially opposed along vertical housing axis 106.

Housing 102 may also include respective front and rear surfaces 102c₁, 102c₂, as well one or more lateral surfaces 102c₁-02c₂. Each of the surfaces 102c, 102d may extend between the top and bottom sides 102a, 102b, and along axis 106.

It will be understood that positional references herein (i.e., top, down, front and rear) are only provided for ease of reference and explanation, and that the features described herein may be oriented in any desired orientation.

In the exemplified embodiment, housing 102 has a generally rectangular exterior design. The rectangular design may accommodate the generally rectangular shape of the processing units 104 (FIGS. 2A, 2B). In other embodiments, housing 102 may have various other exterior design configurations.

As exemplified in FIG. 1B, top surface 102a may include an opening 132. Opening 132 may receive a power cord or wire 134, which is coupled to an external power supply 136. Power cord 134 may supply electric power—from external power supply 136—to the one or more processing units 104 retained inside the housing 102.

As provided in greater detail herein, the housing 102 may be filled with dielectric coolant liquid, which may be used for cooling the processing units 104. Accordingly, by positioning opening 132 along the top housing surface 102a (i.e., as opposed to the lateral or bottom surfaces), the risk of fluid leakage through the opening 132 is reduced, i.e., at least while the housing 102 is in the upright position. In other cases, opening 132 may be located along any other and/or one or more surfaces of the housing 102, and may be a sealed opening.

In some embodiments, best exemplified in FIGS. 2A and 2C, the top housing surface 102a may comprise an openable lid 108. Lid 108 may be removable to access the interior 110 of the housing enclosure 102. By removing lid 108, processing units 104 may be inserted or removed from the housing interior 110. While the exemplified embodiments illustrate lid 108 as being entirely removably, in other embodiments, lid 108 may be openable in any other manner known in the art, e.g., via one or more rotatable hinges. In other cases, rather than the entire top surface 102a being openable, only a portion of the top surface 102a may define an openable potion. In still other cases, the openable portion can be located along any other and/or one or more surfaces of the housing 102.

In operation, each of the processing unit 104 may generate heat, as is typical with computing devices. To prevent overheating of the processing units 104, a cooling mechanism may be provided within the housing 102.

In accordance with at least some conventional designs, the cooling may be performed by submerging the processing units 104 in a dielectric liquid coolant (also known as immersion cooling). The dielectric liquid coolant is an electrically non-conductive liquid that can directly contact the processing units 104, principally owing to its high resistance to electrical breakdown even at high voltages. The dielectric liquid absorbs the thermal energy generated by the processing units 104, thereby cooling the processing units 104.

In the process of absorbing thermal energy from processing units 104, the dielectric liquid may itself increase in temperature and may require its own cooling process. In many cases, this is performed by re-circulating the dielectric liquid through a dielectric cooling system (i.e., an external heat exchanger). For example, heated dielectric liquid is pumped out of the housing 102 into the cooling system. The liquid is then cooled inside the cooling system, and re-circulated back into the housing 102.

An appreciated disadvantage of this setup, however, is that large volumes of dielectric liquid are required to enable constant re-circulation of the liquid between the housing and the dielectric cooling system. Acquiring such large volumes of dielectric liquid can often be prohibitively expensive. Further, the dielectric cooling systems are often complex, expensive and difficult to manage for casual users.

In view of the foregoing, and to at least partially mitigate the aforementioned problems, embodiments herein provide for the use of a cooling water recirculation system. The cooling water recirculation system is provided to cool down dielectric liquid located inside of the housing 102, and is provided as an inexpensive, low complexity alternative to recirculating the dielectric liquid for cooling.

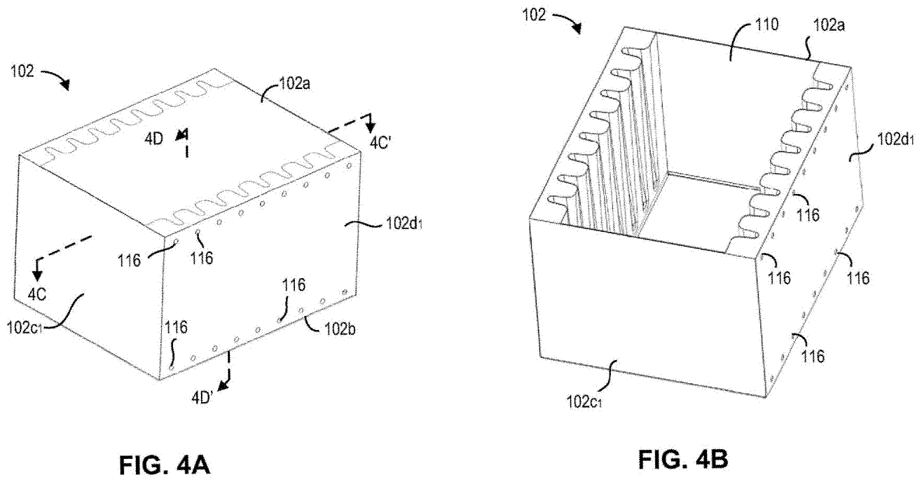

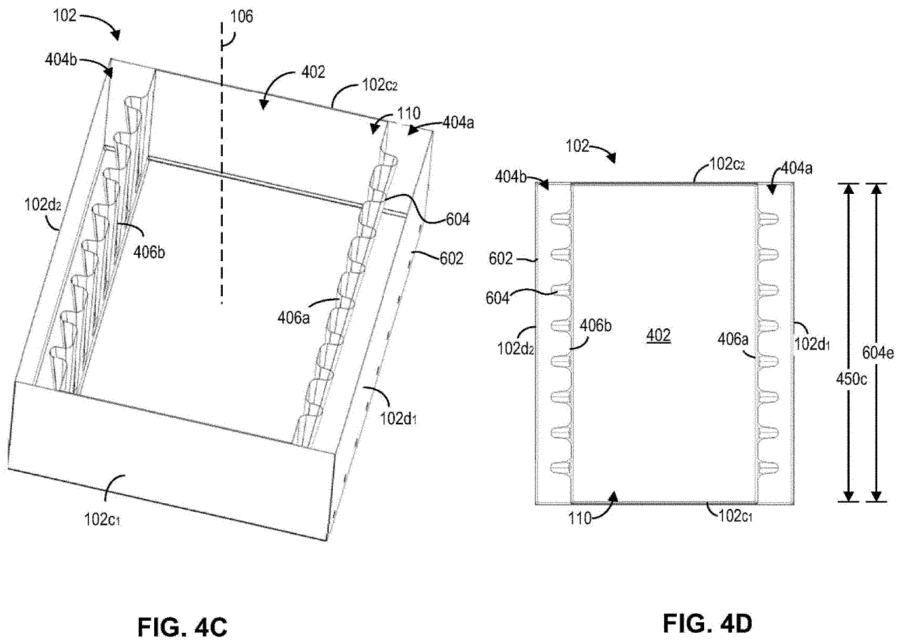

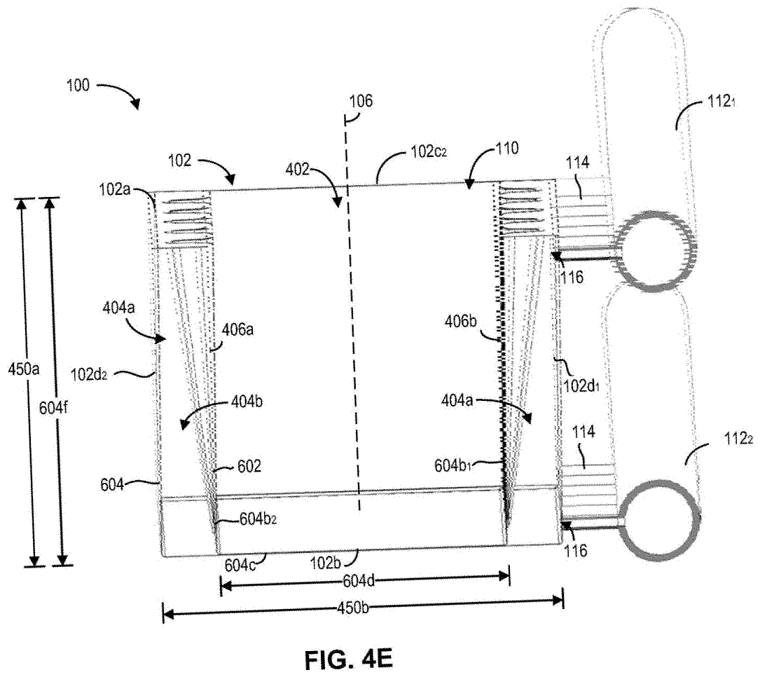

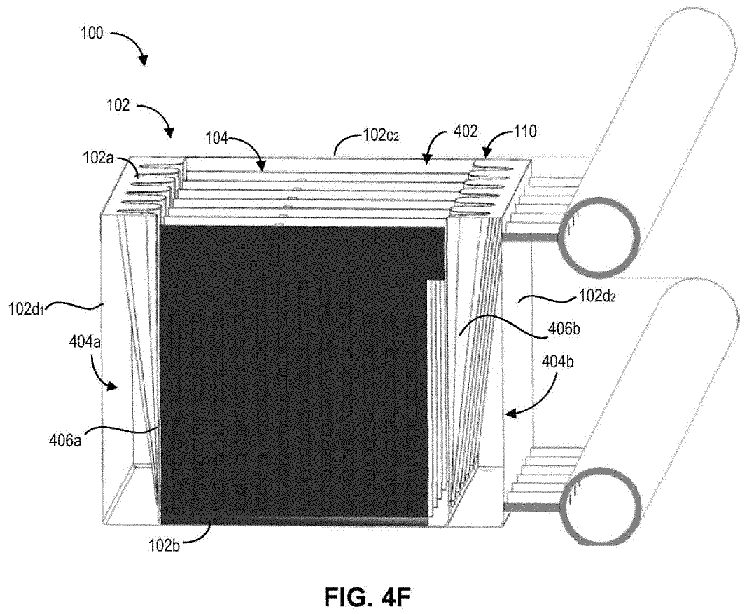

To this end, reference is made to FIGS. 4A-4F, which show various perspective and cross-sectional views of the housing enclosure 102.

As shown, housing 102 may include an interior compartment 402, as well as one or more side chambers 404a, 404b (FIGS. 4C-4E). As best exemplified in FIG. 4F, the interior compartment 402 may be sized and shaped to receive the processing units 104, and may be filled with the dielectric coolant liquid. As explained herein, the side chambers 404a, 404b accommodate a flow of cooling water, which is used to absorb heat from the dielectric liquid inside the compartment 402

As exemplified, the side chambers 404a, 404b may be located proximal the lateral housing faces 102d₁ and 102d₂, and may surround the interior compartment. For example, the interior compartment 402 may be located between the side chambers 404a, 404b (FIGS. 4D, 4E). In some cases, each of the interior compartment 402 and side chambers 404 may extend between the front and rear surfaces 102c₁, 102c₂ of housing 102.

As further shown, the interior compartment 402 is fluidically separated from the side chambers 404a, 404b by respective separation walls 406a, 406b (FIGS. 4A and 4B).

This, in turn, prevents mixing of the dielectric liquid inside the interior compartment 402, with the water flowing through the side chambers 404.

It will be appreciated that the design configuration exemplified in these figures is only provided by way of example, and that other design configurations are possible without departing from the teachings provided herein. For example, in other embodiments, any number of side chambers and interior compartments may be provided, and in any other suitable arrangement.

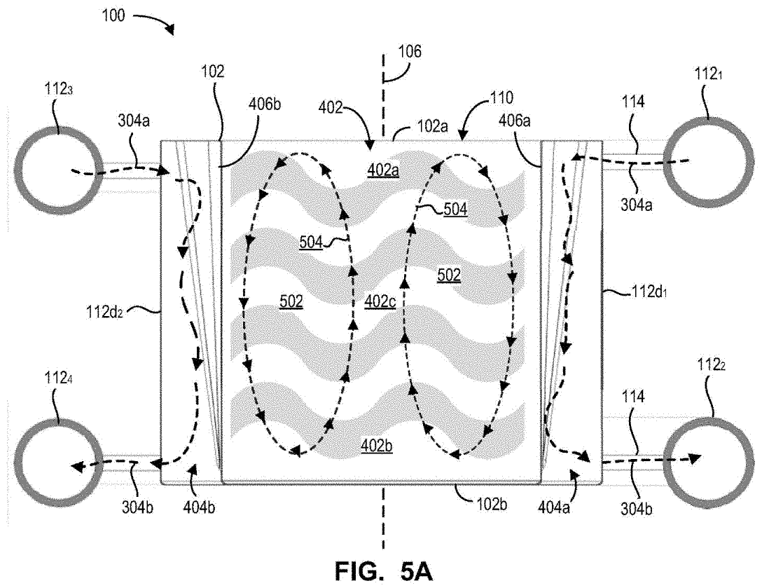

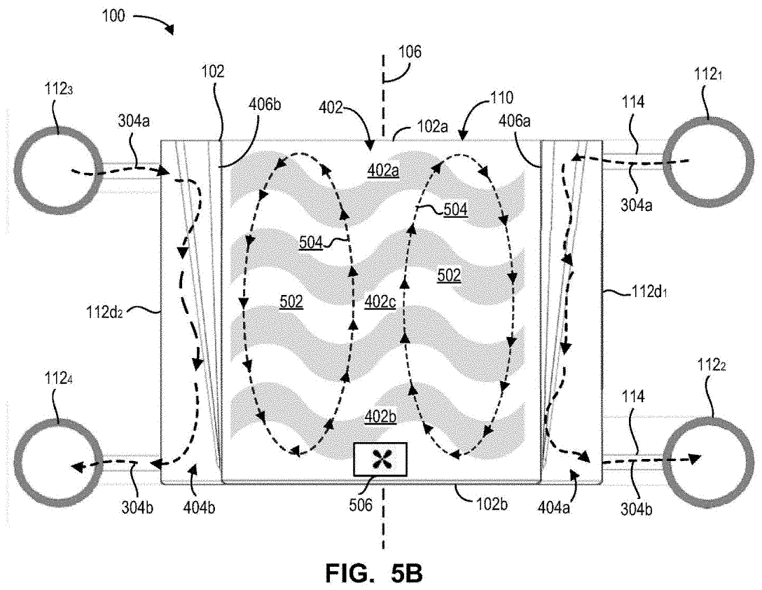

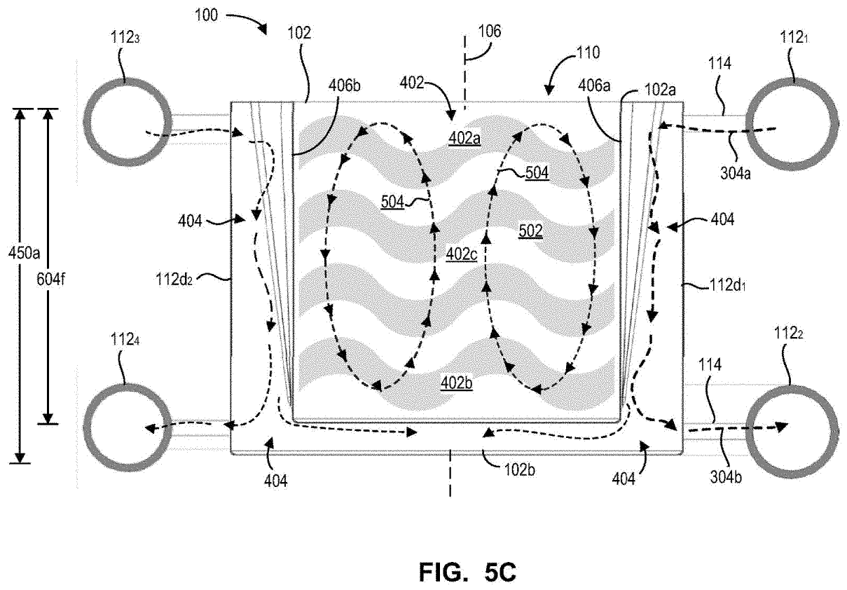

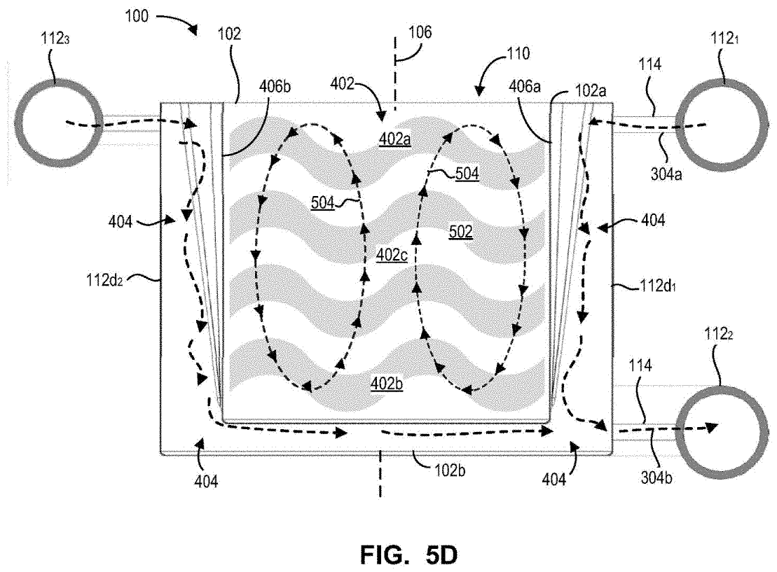

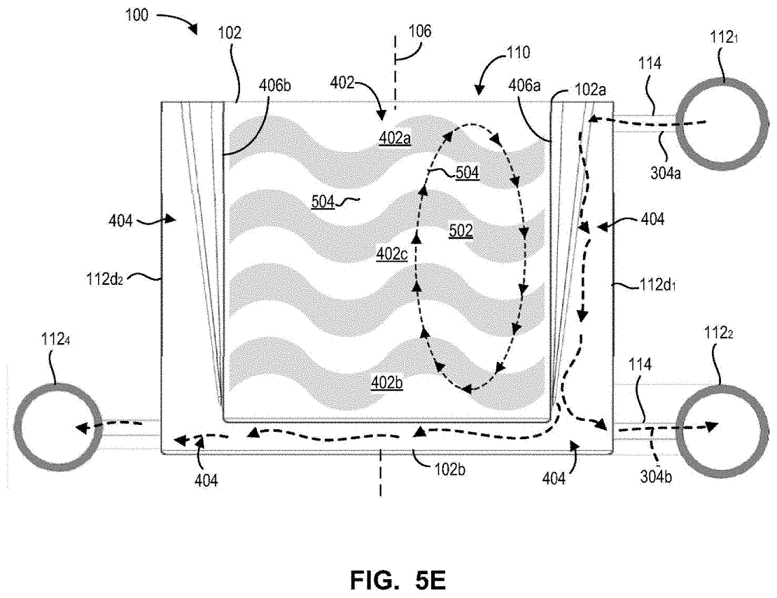

As best exemplified in FIG. 4E, side chambers 404a, 404b are fluidically coupled to one or more fluid conduits 112. While FIG. 4E only illustrates conduits 112 being coupled to the side chamber 404a, it will be understood that the side chamber 404b may also be coupled to conduits 112 (see e.g., FIG. 5A).

As explained herein, fluid conduits 112 are used for transporting lower temperature water into the side chambers 404a, 404b, and for evacuating higher temperature away from the side chambers 404a, 404b.

In the exemplified embodiments (e.g., FIG. 5A), each side chamber 404a, 404b may be coupled to two conduits 112. For instance, first side chamber 404a may be coupled to fluid conduits 112₁, 112₂, while second side chamber 404b may be coupled to fluid conduits 112₃, 112₄. In the upright position, the conduits may be vertically positioned relative to each other such that each side chamber 404 may be connected to both a respective upper fluid conduit 112₁, 112₃ and a respective lower fluid conduit 112₂, 112₄. In other cases, any number of fluid conduits 112 may be coupled to each side chamber 404.

As exemplified in FIG. 4A-4B and 4E, conduits 112 may couple to the side chambers 404 via one or more connectors 114. One or more openings 116 may line the lateral housing surfaces 102d₁, 102d₂, and may act as the coupling points between connectors 114 and side chambers 404.

As stated above, with respect to each side chamber 404, one of the fluid conduits may be used to transport cooled water into the respective side chamber 404, while the other fluid conduit 112 may be used to evacuate heated water away from the respective side chamber 404.

For instance, in the exemplified embodiments, the upper fluid conduits 112₁, 112₃ may transport the lower temperature 304a water into side chambers 404a, 404b, while the lower fluid conduits 112₂, 112₄ may transport the higher temperature water away from the side chambers 404a, 404b.

As exemplified in FIG. 5A, in operation, cooled water flows into the upper portion of each side chamber 404, via the respective upper fluid conduit 112₁, 112₃. Subject to the influence of gravity, the water may flow downwardly, such that the water flows from the upper portion to the lower portion of each side chambers 404. As the water flows downwardly, heat is exchanged from the dielectric liquid 502 (i.e., located inside the inner compartment 402) to the flowing water 304 (i.e., located inside the side chambers 404). That is, the heat is exchanged through the separation walls 406a, 406b, which separate the inner compartment 402 from the side chambers 404. The heat is then absorbed by the flowing cooled water such that higher temperature water 304b is then evacuated through the lower fluid conduits 112₂, 112₄.

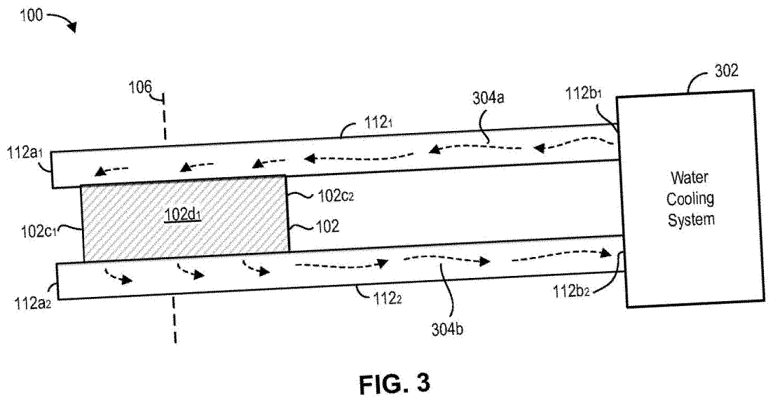

As shown in FIG. 3, each fluid conduit 112 may extend between a respective first end 112a and a distal second end 112b. The first end 112a fluidically connects to the side chambers 404a, 404b, while the second end 112b connects to a water cooling system 302.

Water cooling system 302—which may be a heat exchanger—pumps cooled water through the upper conduits 112₁, 112₃, such that water travels from the respective second conduit end 112b to the first conduit end 112a. As explained above, the water enters and circulates through the respective housing side chambers 404. The higher temperature water is then returned back to the water cooling system 302, via the lower conduits 112₂, 112₄. Water cooling system 302 cools the higher temperature water and re-circulates (i.e., pumps) the cooled water back to the housing enclosure 102 to again re-cool the dielectric coolant liquid.

A number of advantages will now be appreciated with respect to the disclosed system. For example, rather than circulating and cooling the dielectric liquid, the disclosed system recirculates water in order to cool the dielectric liquid, which remains inside the inner compartment 402. To this end, the process of cooling water is significantly less complex and cost-effective than the process of cooling the dielectric liquid. Further, the use of a large volume of recirculating water is also more cost effective than using a large volume of recirculating dielectric liquid.

Referring back to FIG. 5A, within the interior compartment 402—owing to the thermal properties of the dielectric liquid 502, heated dielectric liquid will typically rise to the top area 402a of the compartment 402, while cooled dielectric liquid will sink to the bottom area 402b of the compartment 402. In this manner, cooled water 304a—flowing through the upper conduits 112₁, 112₃—is positioned to absorb heat from the rising heated dielectric liquid, i.e., in upper compartment area 402a. Once heat is transferred away from the dielectric liquid 502, the cooled dielectric liquid 502 may sink back to the lower compartment area 402b. In turn, the dielectric fluid 502 may experience internal currents 504, whereby cooled dielectric liquid 502 sinks along the lateral sides of compartment 402 adjacent the side chambers 404, while heated dielectric liquid 502 will rise upwardly through a central portion of the compartment 402.

In at least one embodiment, best exemplified in FIG. 5B, one or more agitator units 506 may be positioned within the interior compartment 402. For instance, agitator units 506 may be positioned in a lower portion 402b of each compartment unit 402. Agitator units 506 can comprise, for example, fan blades, or the like. The agitator units 506 may function to propel the heated dielectric liquid 502 back towards the upper portion 402a of the compartment 402. In this manner, the dielectric liquid 502 may be positioned for quick cooling by the incoming cool water flow 304a from the upper conduits 112₁, 112₃. In other words, the agitator(s) 506 are used to catalyze the current flow 504 to increase the speed of cooling of the dielectric liquid 502. In some embodiments, agitator units 506 may be positioned centrally, between the separation walls 406a, 406b to propel the heated dielectric liquid 502 upwardly, through the central portion of the compartment 402.

In some embodiments, the flow path of the water may be reversed. For example, cool water may enter through the lower conduits 112₂, 112₄ while hot water may exit from the upper conduits 112₁, 112₃. In these cases, a pump mechanism may be provided to pump the water vertically upwards from the lower conduits 112₂, 112₄ to the upper conduits 112₁, 112₃. For example, the pump mechanism (i.e., an agitator) may be positioned inside the respective side chamber 404 and/or inside the fluid conduits.

It will also be appreciated that the fluid conduits 112 may not be necessarily vertically stacked. In so far as cooled water can be injected into the side chambers 404, and the heated water can be removed—any positional arrangement and/or number of fluid conduits may be provided.

Further, while exemplified embodiments illustrate two lateral side chambers 404a, 404b it will also be understood that various other configurations are possible. For example, the housing 102 may include multiple side chambers 404, along each lateral face 112d₁, 112d₂. Each of the multiple side chambers 404 may be individually coupled to one or more fluid conduits which supply cooling water, and excavate heated water. Additionally, or alternatively, side chambers may be located along any other surface of the housing 102, in 25 so far as the chambers can be used to exchange heat between the dielectric liquid inside the interior compartment 402 and the water flowing through the chambers 404. For instance, the chambers may be located proximal the front and/or rear faces 112c₁, 112c₂, or along the top and/or bottom faces 112a, 112b, of housing 102. Each of these chambers may be connected to respective water fluid conduits 112.

In some cases, as exemplified in FIG. 5C, the side chambers 404a, 404b may be fluidically coupled to provide a single integrated chamber 404. For example, the interior compartment 402 may have a reduced volume size such that the chamber 404 may wrap around a lower portion 402b (or any other portion) of the interior compartment 402. In these cases, it may not be necessary to have four fluid conduits 112 to accommodate two separate chambers 404. For instance, as exemplified in FIG. 5D, there may be two upper fluid conduits 112₁, 112₃ for transporting cooled water 304a, and a single lower conduit 112₂ (or 112₄) for evacuating heated water. In other cases, as exemplified in FIG. 5E, there may be a single upper fluid conduit 112₁(or 112₃) for transporting cooled water 304a, and two lower conduits 112₂ (or 112₄) for evacuating heated water 304b. In still other cases (not shown), there may be a single upper and lower fluid conduit.

Referring now to FIGS. 4C and 4D, the separation walls 406a, 406b may be designed to maximize heat transfer between the dielectric liquid (i.e., inside the interior compartment 402) and the water flow (i.e., inside the side chambers 404).

For instance, as exemplified, the separation walls 406a, 406b may have an at least partially corrugated (i.e., zigzag) design. That is, the separations walls 406a, 406b may fold inwardly and outwardly between the sidewall chambers 404 and the interior compartment 402. An advantage of this corrugated design—i.e., as opposed to a flat or planar design—is to increase the surface area through which heat can be conducted from the interior compartment 402 to the side chambers 404.

As best exemplified in FIG. 4C, 4E and 5A, in some embodiments, the corrugated portion may be emphasized towards the top area 402a of the interior compartment 402. This is because the lower temperature water may be received near the top via the upper fluid conduit 112₁ and/or 112₃ (i.e., water flow 304a in FIG. 5A), and accordingly, the heat exchange is likely to occur near the top portion. Therefore, the heat transfer is improved by corrugating the top portion of the separation walls 406. Further, the lower portion of the separation walls 406a, 406b may be flat or planar to minimize reverse heat transfer from the heated water 304b, back to the cooled dielectric liquid 502 near the bottom compartment area 402b.

In other embodiments, any other design configurations for the separation walls 406 may be used to increase the surface area, as between the interior compartment 402 and the side chambers 404, to improve heat exchange.

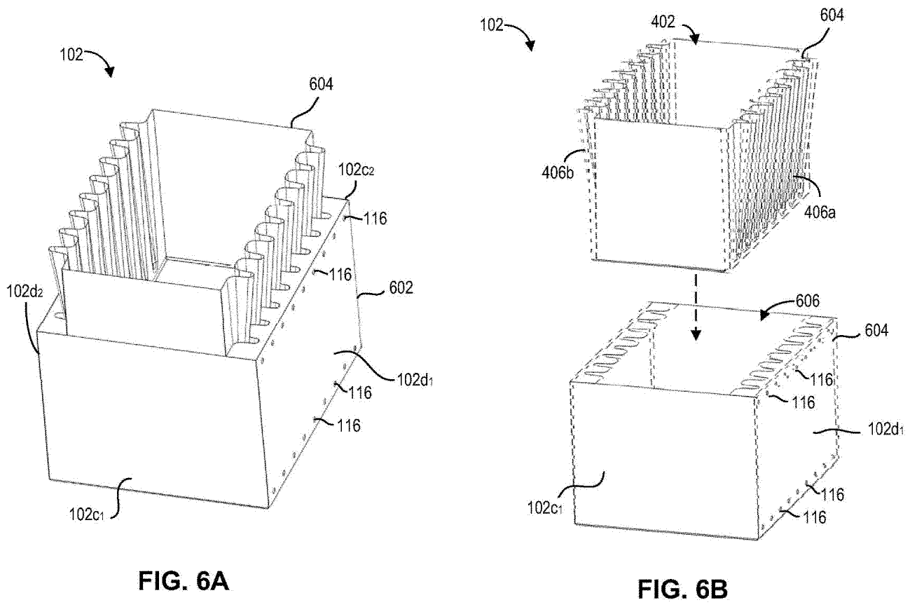

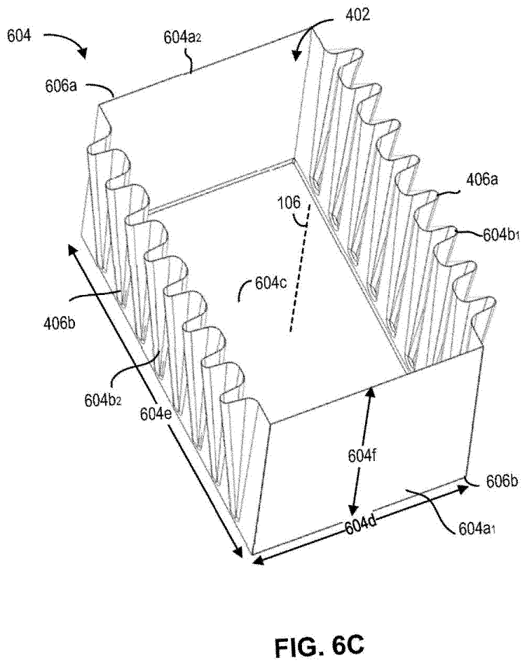

Reference is now made to FIGS. 6A-6D, which exemplify example methods for assembling the housing enclosure 102.

As exemplified in these figures, the housing enclosure 102 may comprise a two-piece assembly, which may include an outer housing structure 602, and an inner housing structure 604. The inner housing structure 604 may be nested within the outer housing structure 602.

The outer housing structure 602 may define the outside of the housing enclosure 102, i.e., defining the front and rear surfaces 102c₁, 102c₂as well as the lateral surfaces 102d₁, 102d₂. Outer housing structure 602 may include a hollow interior 606, which receives the interior structure 604.

As exemplified, the interior structure 604 may define the inner compartment 402 of the housing 102, i.e., the compartment receiving the processing units 104 and the dielectric liquid. As shown by example in FIG. 6C, the interior structure 604 may include a front surface 604a₁ and a distally opposed rear surface 604a₂, as well as opposed lateral surfaces 604b₁, 604b₂ and a lower surface 604c. As explained herein, the lateral surfaces 604b₁, 604b₂ may define the respective separation walls 406a, 406b, which fluidically isolate the interior compartment 402 from the side chambers 404.

As shown in FIG. 6C, a width dimension 604d may be defined between the lateral surfaces 604b₁, 604b₂, and a length dimension 604e may be defined between the front and rear surfaces 604a₁, 604a₂, whereby each of the width and length are defined in an axis orthogonal to axis 106. A height dimension 604f may be further defined, along axis 106, as between an upper end 606a and a lower end 606b of the structure 604. A volume dimension is defined with respect to the width 604d, length 604e and height 604f.

In the exemplified embodiment, the upper end 606a may comprise an at least partially open end, which can allow inserting the processing units 104 and the dielectric liquid.

As best exemplified in FIG. 4E, the width 604d—of the interior housing structure 604—may be smaller than the width 450b of the exterior housing structure 602, such as to define the side chambers 404a, 404b. That is, the lateral surfaces 604b₁, 604b₂ of the interior structure 604, may be recessed inwardly—along an axis orthogonal to axis 106—to define the side-chambers 404. The width of the exterior housing 602 may be defined between the lateral faces 102d₁ and 102d₂.

In at least some embodiments, the height 604f—of the interior housing structure 604—may also be less than the height 450a of the exterior structure 602 (FIG. 5C). In this manner, the side chambers 404a, 404b may be fluidically coupled to form a single chamber. In other cases, the side chambers 404 may be fluidically coupled in any other suitable manner. For example, the length 450c of the exterior structure 602 (FIG. 4D) may be less than the length 604e of the interior structure 602. In still other cases, the volume of the interior structure 604 may be generally smaller than the volume of the exterior structure 602.

In some embodiments, the interior structure 602 may be formed from a metal, or otherwise, a material with high heat transfer properties (i.e., aluminum or copper). In some cases, the interior structure 602 may be manufactured from a single sheet of metal, which is stamped or molded to take the shape configuration exemplified in FIG. 6C.

In other cases, the housing 102 may be manufactured from a single integrated piece, or any number of assembled pieces.

While the above description provides examples of the embodiments, it will be appreciated that some features and/or functions of the described embodiments are susceptible to modification without departing from the spirit and principles of operation of the described embodiments. Accordingly, what has been described above has been intended to be illustrative of the invention and non-limiting and it will be understood by persons skilled in variants and modifications may be made without departing from the scope of the invention as defined in the claims appended hereto. The scope of the claims should not be limited by the preferred embodiments and examples, but should be given the broadest interpretation consistent with the description as a whole.

I claim:

1. An immersion tank assembly, comprising:
a tank housing enclosure, the enclosure comprising:
at least one interior compartment configured to retain one or more processing units immersed in dielectric cooling liquid;
one or more side chambers surrounding the interior compartment, wherein the one or more side chambers are fluidically isolated from the interior compartment by one or more separation walls; and
one or more fluid conduits in fluid communication with the each of the one or more side chambers, wherein the one or more fluid conduits are adapted to convey lower temperature water into the respective side chamber for cooling the dielectric cooling liquid in the at least one interior compartment, and to evacuate higher temperature water away from the respective side chamber.

2. The assembly of claim 1, wherein the separation walls are corrugated to maximize heat transfer between interior compartment and the side chambers.

3. The assembly of claim 1, wherein the tank housing enclosure comprise a bottom side and a top side, the top side being axially opposed from the bottom side along a vertical axis, and each of the one or more side chambers extends between the top and bottom sides.

4. The assembly of claim 3, wherein each fluid conduit, of the one or more fluid conduits, extends between a first end and a second end, the first end being fluidically coupled to a respective side chamber and the second end being fluidically coupled to a water cooling system.

5. The assembly of claim 4, wherein the one or more fluid conduits, coupled to each side chamber, comprise a first fluid conduit and a second fluid conduit, the first fluid conduit being used to transport cooled water from the water cooling system into the respective side chamber and the second fluid conduit being used to transport heated water away from the respective side chamber and back to the water cooling system.

6. The assembly of claim 5, wherein the first fluid conduit is an upper fluid conduit coupled to an upper portion of each side chamber, and the second fluid conduit is a lower fluid conduit coupled to a lower portion of each side chamber.

7. The assembly of claim 1, further comprising one or more agitators positioned inside the at least one interior compartment.

8. The assembly of claim 1, wherein the immersion tank assembly comprises an interior housing structure nested within an exterior housing structure, and the interior housing structure defines the interior compartment.

9. The assembly of claim 8, wherein the interior housing structure has a smaller volume size than the exterior housing structure such as to define the side chambers.

10. The assembly of claim 8, wherein the interior housing structure is manufactured from a heat conductive metal.
